(19) United States
(12) Patent Application Publication
(10) Pub. No.: US 2007/0272939 A1
(43) Pub. Date: Nov. 29, 2007

(54) Tunnel vertical semiconductor devices or chips

(76) Inventor: Hui Peng, Fremont, CA (US)

Correspondence Address: Hui Peng, 35964 Vivian Place, Fremont, CA, 94536, US

(21) Appl. No.: 11/807,121

(22) Filed: May 25, 2007

(30) Foreign Application Priority Data
May 29, 2006 (CN) 200610081556.3

(51) Int. Cl. H01L 33/00

(52) U.S. Cl. 257/99

(57) ABSTRACT

The present invention discloses tunnel vertical semiconductor devices and chips comprising tunnel vertical GaN based, GaP based and ZnO based LEDs and manufacturing method. The structure of an embodiment of tunnel vertical semiconductor devices and chips is the following: first and second electrodes formed on first surface of a supporting silicon chip; third and fourth electrodes formed on second surface of the supporting silicon chip. First and second electrodes are respectively electrically connected with third and fourth electrodes. The position and shape of second electrode correspond to that of the reflector/Ohmic/bonding layer of a semiconductor chip, while the position and shape of first electrode is corresponded to that of a protection plug. A half-tunnel-metal-plug electrically connects a patterned electrode deposited on a current spreading layer to the first electrode on the first surface of the supporting silicon chip.

### BACKGROUND OF THE INVENTION

(1) Field of the Invention

The present invention discloses tunnel vertical semiconductor devices or chips comprising tunnel vertical semiconductor GaN based, GaP based, GaNP based and ZnO based devices or chips (comprising tunnel vertical GaN based, GaP based, GaNP based and ZnO based LED) and low cost methods of manufacturing the same.

(2) Prior Art

High power LEDs have huge market potential, especially after resolving technique and manufacture issues. In order to resolve the issues of absorbing emitted light of GaAs substrates of GaP based LEDs and low heat dispassion rate of sapphire substrates of GaN based LEDs, vertical GaP and GaN based LEDs have been disclosed respectively (U.S. Pat. No. 5,008,718, U.S. Pat. No. 5,376,580 and U.S. Pat. No. 5,502,316). The basic structure of vertical GaP and GaN based LEDs is the following: a reflector/Ohmic layer deposited on GaP based or GaN based epitixy layer, the other side of the reflector/Ohmic layer is bonded to an electrical conductive supporting substrate (comprising conductive silicon wafer, conductive GaP wafer, conductive GaAs wafer, metal, alloy, etc), while the original growth substrate has been removed, forming vertical GaP and GaN based LEDs.

However there is at least one wire to be bonded to the above mentioned LEDs for connecting the LED to external power source. Wire bonding has reliability issue and causes thicker LED packages. Also burn-in process has to be done after packaging the LED chip, which causes uncertainty of chip quality before packaging. Once the chip is not qualified, then the whole package is failed and hard to re-work, and the cost is increasing.

In order to resolve the above mentioned issues, the tunnel lateral flip chip GaN based LED with static protection diode has been disclosed (i.e., lateral GaN LED is flip chip bonded onto supporting silicon chip with static protection diode in it. However it is needed to improve the efficiency of lateral LED.

Therefore there is a need for tunnel vertical semiconductor devise of chip (comprising GaN based, GaP based, GaNP based and ZnO based LED chips) to resolve the above mentioned reliability, burn-in, and thickness issues.

### BRIEF SUMMARY OF THE INVENTION

The present invention discloses tunnel vertical semiconductor devises or chips (with or without static protection diode). An embodiment of a tunnel vertical semiconductor devise or chip with a static protection diode comprises (FIG. 2f): each of two surfaces of a supporting silicon chip has two electrodes. The two electrodes on the same surface are isolated to each other. Two electrodes on the first surface are electrically connected with two electrodes of the second surface respectively. There is a static protection diode 212 formed inside of the supporting silicon chip. The first and second electrodes on the first surface of the supporting silicon chip are electrically connected with two polarities of the static protection diode respectively. The position and shape of the second and first electrodes 206 and 207 corresponds respectively with that of the reflector/Ohmic/bonding layer 205 and protection plug 214. Half-tunnel-metal-plug 217 is formed in the half-tunnel 216 (FIG. 2e) and electrically connects first electrode 207 to patterned electrode 218 formed on current spreading layer 215. First cladding layer 202, active layer 203 and second cladding layer 204 are formed in the order presented between the current spreading layer 215 and the reflector/Ohmic/bonding layer 205.

An embodiment of a tunnel vertical semiconductor device or chip without static protection diode has the structure as the following (FIG. 3a): the position and shape of second and first electrodes 306 and 307 corresponds respectively with that of the reflector/Ohmic/bonding layer 305 and protection plug 314 embedded in the epitaxy layer. Half-tunnel-metal-plug 317 is formed in the protection plug 314 and electrically connects first electrode 307 to patterned electrode 318 formed on current spreading layer 315. First cladding layer 302, active layer 303 and second cladding layer 304 are formed in the order presented between current spreading layer 315 and reflector/Ohmic/bonding layer 305.

An embodiment of process of manufacturing tunnel vertical semiconductor devices or chips with static protection diodes is as the following:

(1) manufacturing supporting silicon wafer with static protection diode:

Forming plurality of static protection diodes at predetermined positions in an isolated supporting silicon wafer. Depositing metal/alloy layers on both surfaces of the supporting silicon wafer. Forming plurality of sets of electrodes at predetermined positions on the first surface of the silicon supporting wafer. Each set of electrodes contains first and second electrodes which are electrically isolated to each other. The positions and shapes of the first and second electrodes correspond respectively to that of the protection plug and reflector/Ohmic/bonding layer. The first and second electrodes are electrically connected respectively with two polarities of the static protection diode. Forming plurality of sets of electrodes at predetermined positions on the second surface of the silicon supporting wafer. Each set of electrodes contains third and fourth electrodes which are electrically isolated to each other. The positions and shapes of the third and fourth electrodes are pre-determined. The positions of the third and fourth electrodes on the second surface correspond respectively to that of the first and second electrodes on the first surface. Forming plurality of tunnels at predetermined positions and depositing metal-plugs into the tunnels such that a first electrode is electrically connected to a third electrode by at least one plug and a second electrode is electrically connected to a fourth electrode by at least one plug to form a supporting silicon wafer with static protection diodes in the supporting silicon wafer.

(2) Depositing electrically conductive reflector/Ohmic/bonding layer on the second cladding layer of an epitaxy wafer. Then the first surface of the supporting silicon wafer is bonded to the reflector/Ohmic/bonding layer to form a compound epitaxy wafer.

(3) Removing the growth substrate of the epitaxy wafer until the first cladding layer exposed.

(4) At pre-determined positions which correspond to first electrodes on first surface of the supporting silicon wafer, etching the epitaxy layer until a portion of the reflector/Ohmic/bonding layer exposed.

(5) Depositing a protection plug on the exposed portion of patterned reflector/Ohmic/bonding layer, such that the first electrodes do not directly electrically contact the second electrodes, the first-type cladding layer, the active layer and the second cladding layers.

(6) Depositing a current spreading layer on the first cladding layer and the protection plug.

(7) At pre-determined positions which correspond to the first electrodes on the first surface of the supporting silicon wafer, etching the current spreading layer and the protection plug until a portion of the reflector/Ohmic/bonding layer exposed to form half-tunnels.

(8) Forming a half-tunnel-metal-plug in each of half-tunnels.

(9) Depositing patterned electrodes on the surface of the current spreading layer. Patterned electrodes are electrically connected with half-tunnel-metal-plugs respectively at pre-determined positions.

(10) Dicing the compound epitaxy wafer to form semiconductor devices or chips.

The quantities and area of cross section of the metal-plugs which electrically connected a pair of corresponding electrodes on the first and second surfaces of the supporting silicon wafer are pre-determined. The advantages of using more than one metal-plugs to electrically connect the pair of corresponding electrodes on the first and second surfaces of the supporting silicon wafer are the following: (1) improving the heat dissipation efficiency further; (2) decreasing series electrical resistance and, thus, reducing the forward voltage and generating less heat.

The objects of the present invention are the following:
(1) The primary object is to provide tunnel vertical semiconductor (comprising GaN based, GaP based, GaNP based and ZnO based) devices or chips (comprising GaN based LED, GaP based LED, GaNP based LED and ZnO based LED) to resolve the above mentioned efficiency, burning-in and wire bonding issues.
(2) The second object is to provide a method for mass production of the tunnel vertical semiconductor devices or chips.
(3) The third object is to provide tunnel vertical semiconductor devices or chips with static protection diodes to resolve the above mentioned efficiency, burning-in and wire bonding issues.
(4) The fourth object is to provide a low cost method for mass production of tunnel vertical semiconductor devices or chips with static protection diodes.
(5) The fifth object is to provide an embodiment of integration between semiconductor chips or devices with IC chips or devices.

Further objects and advantages of the present invention will become apparent from a consideration of the ensuing description and drawings.

### BRIEF DESCRIPTION OF THE SEVERAL VIEWS OF DRAWINGS

The novel features believed characteristic of the present invention are set forth in the claims. The invention itself, as well as other features and advantages thereof will be best understood by referring to detailed descriptions that follow, when read in conjunction with the accompanying drawings.

FIG. 1a shows a semiconductor epitaxy wafer (comprising GaN based, GaP based, GaNP based and ZnO based).

FIG. 1b shows an embodiment of a supporting silicon wafer with or without of static protection diodes.

FIG. 2a to FIG. 2f show first embodiment of a process of making tunnel vertical semiconductor (comprising GaN based, GaP based, GaNP based and ZnO based) devices or chips.

FIG. 2g to FIG. 2i show second embodiment of a process of making tunnel vertical semiconductor (comprising GaN based, GaP based, GaNP based and ZnO based) devices or chips.

FIG. 2j shows third embodiment of a process of making tunnel vertical semiconductor (comprising GaN based, GaP based, GaNP based and ZnO based) devices or chips.

FIG. 3a shows first embodiment of a tunnel vertical semiconductor device or chip.

FIG. 3b shows second embodiment of a tunnel vertical semiconductor device or chip.

FIG. 3c shows third embodiment of a tunnel vertical semiconductor device or chip.

FIG. 4 shows an embodiment of a schematic process of making tunnel vertical semiconductor devices or chips.

FIG. 5a shows first embodiment of the shapes and positions of both first electrode and second electrode on the first surface of a supporting silicon chip. The supporting silicon chip may or may not comprise a static protection diode.

FIG. 5b shows an embodiment of the shapes and positions of both a half-tunnel-metal-plug and patterned electrode of the tunnel vertical semiconductor device or chip corresponding to the supporting silicon chip of FIG. 5a.

FIG. 6a shows second embodiment of the shapes and positions of both first electrode and second electrode on the first surface of a supporting silicon chip. The supporting silicon chip may or may not comprise a static protection diode.

FIG. 6b shows an embodiment of the shapes and positions of both a half-tunnel-metal-plug and patterned electrode of the tunnel vertical semiconductor device or chip corresponding to the supporting silicon chip of FIG. 6a.

FIG. 7a shows third embodiment of the shapes and positions of both first electrode and second electrode on the first surface of a supporting silicon chip. The supporting silicon chip may or may not comprise a static protection diode.

FIG. 7b shows an embodiment of the shapes and positions of both a half-tunnel-metal-plug and patterned electrode of the tunnel vertical semiconductor device or chip corresponding to the supporting silicon chip of FIG. 7a.

### DETAILED DESCRIPTION OF THE INVENTION

While embodiments of the present invention will be described below, the following description is illustrative the principle only and not limiting to the embodiments.

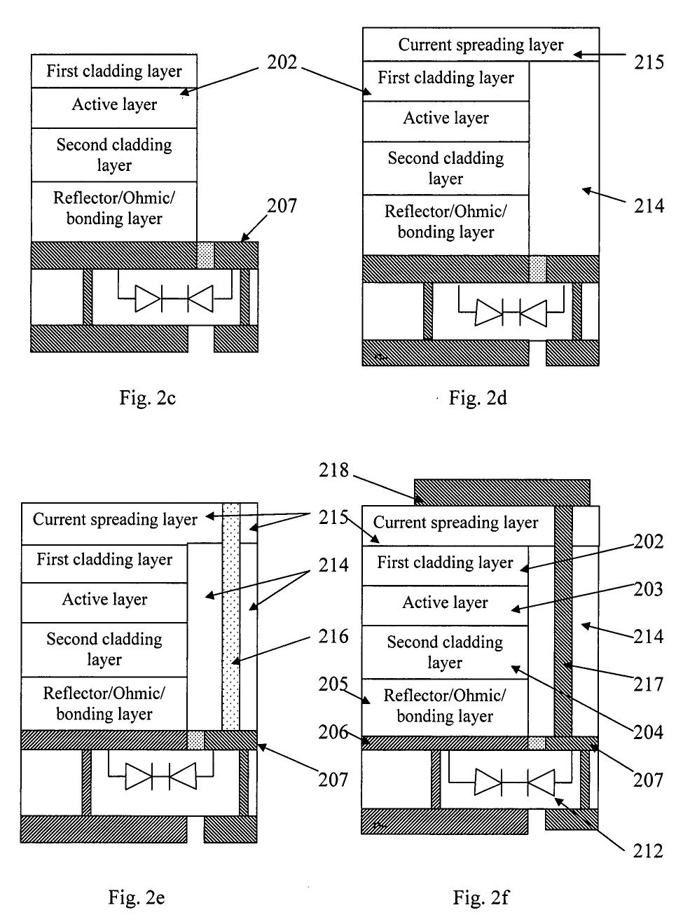

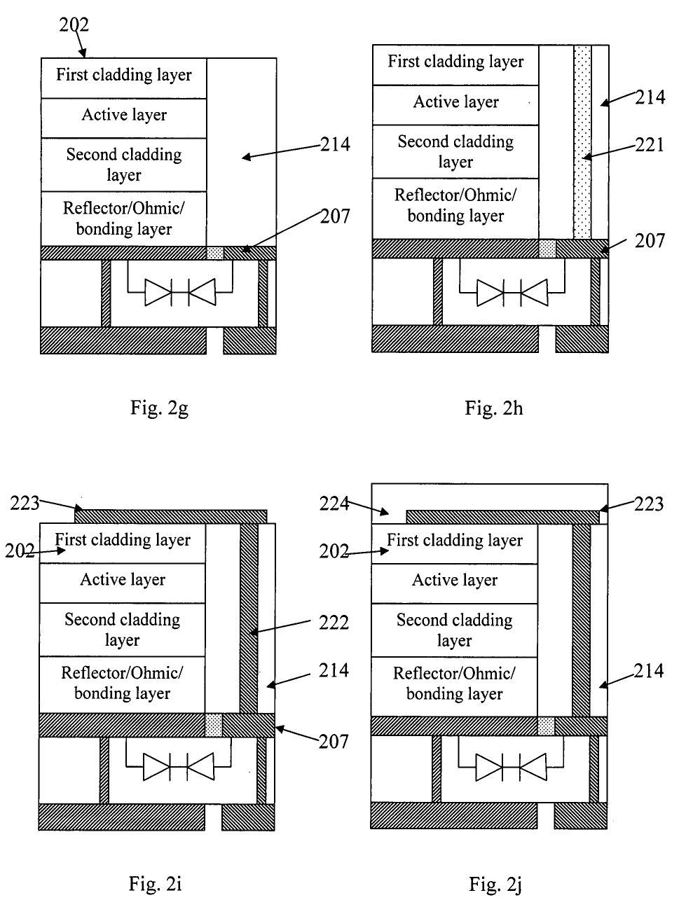

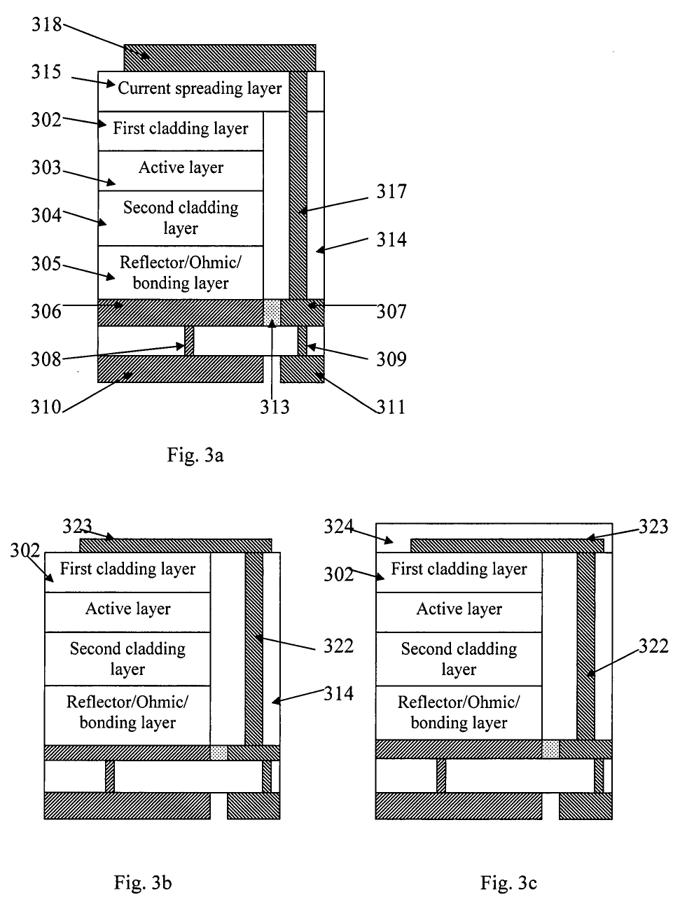

Note the followings:
(1) Tunnel vertical semiconductor devices or chips of the present invention comprise: GaN based, GaP based and GaNP based chips or devises. Wherein the material systems of GaN based chips or devises comprise the combinations of elements of Gallium, Aluminum, Indium and Nitrogen which comprising GaN, GaInN, AlGaInN; the materials of GaP based chips or devises comprise the combinations of elements of Gallium, Aluminum, Indium and Phosphor which comprising GaP, GaInP, AlGaInP; the materials of GaNP based chips or devises comprise the combinations of elements of Gallium, Aluminum, Indium, Nitrogen and Phosphor which comprising GaNP, GaInNP, AlGaNP, AlGaInNP; the materials of ZnO based chips or devises comprise the combinations of elements of Zinc and Oxygen which comprising ZnO. GaN based, GaP based and GaNP based tunnel vertical semiconductor chips or devises comprise GaN based LED, GaP based LED and GaNP based LED. The GaN based epitaxy layers comprise polar and non-polar layers.
(2) The manufacturing methods of tunnel vertical semiconductor devices or chips (with or without static protection diodes) of the present invention are at wafer level and the last process is dicing the compound wafer into individual chips or devices. Since a wafer includes a plurality of same chips or devices, in FIG. 2 and FIG. 3, using one chip or device to illustrate the manufacturing process.
(3) The present invention provides an embodiment of integration of a semiconductor chip or device and an IC device.
(4) There is no need to wire bond the patterned electrode on the top surface to connect to the out power. The patterned electrode is electrically connected to the half-tunnel-metal-plug which electrically connected to the first electrode on the first surface of the supporting silicon chip, and the first electrode is electrically connected to the third electrode on the second surface of the supporting silicon chip. The second electrode on the first surface of the supporting silicon chip is bonded to the most area of the second cladding layer and, thus, tunnel vertical semiconductor chips or devices have all of advantages of a vertical chip or device, such as current crowding effect is much smaller, much higher current density can be employed, and the heat dissipation efficiency is much higher.
(5) The capability of protection of static discharge is much higher.
(6) The light extraction is higher because that there is a reflector/Ohmic/bonding layer between the second cladding layer and the supporting silicon chip.
(7) The area of a half-tunnel-metal-plug is smaller than that of a wire bonding pad, therefore less output light is blocked.
(8) There is no need of wire bonding. The chips or devices may be burn-in before package and, thus, increasing yield and decreasing the cost. The total thickness of package is reduced. The reliability is improved.

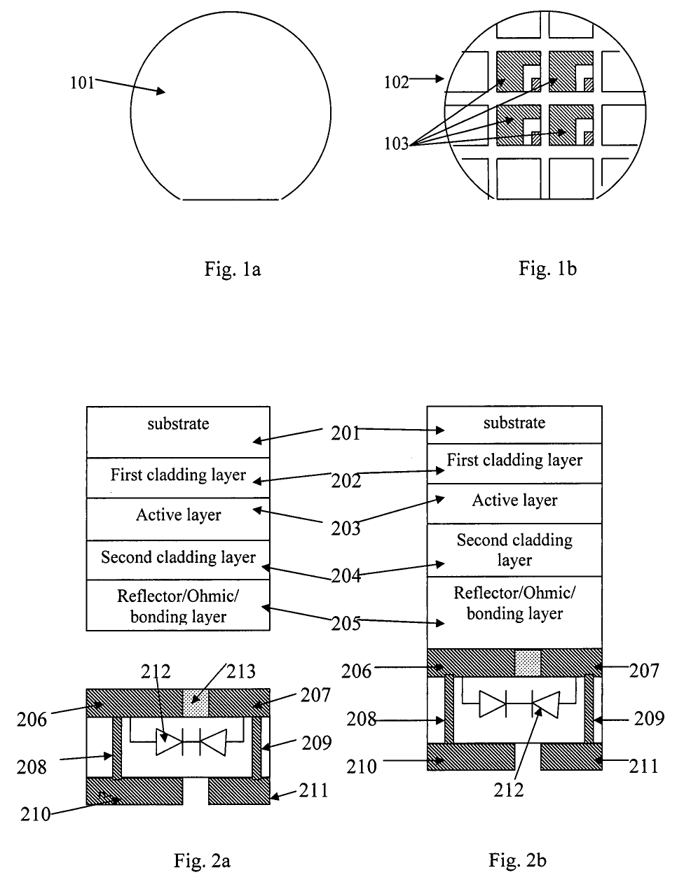

FIG. 1a shows a semiconductor (GaN based, GaP based, GaNP based and ZnO based) epitaxy wafer 101 comprising a growth substrate, a buffer layer, a first-type cladding layer, an active layer, a second-type cladding layer, and an electrically conductive reflector/Ohmic/bonding layer depositing on the second cladding layer. Wherein the structures of the active layer comprise bulk, single quantum well, multi-quantum well, quantum dot, and quantum line. The material systems of the epitaxy layer comprise the combinations of elements of Gallium, Aluminum, Indium and Nitrogen which comprising GaN, GaInN, AlGaInN; the materials of GaP based chips or devises comprise the combinations of elements of Gallium, Aluminum, Indium and Phosphor which comprising GaP, GaInP, AlGaInP; the materials of GaNP based chips or devises comprise the combinations of elements of Gallium, Aluminum, Indium, Nitrogen and Phosphor which comprising GaNP, GaInNP, AlGaNP, AlGaInNP; the materials of ZnO based chips or devises comprise the combinations of elements of Zinc and Oxygen which comprising ZnO.

FIG. 1b shows a supporting silicon wafer with size and shape as that of the semiconductor epitaxy wafer 101 of FIG. 1a. The supporting silicon wafer is with or without static protection diodes. Supporting silicon wafer 102 and supporting silicon chip are not scaled to the real size. For simplifying the figures, only 4 supporting silicon chip 103 are drawn on silicon supporting wafer 102, although there is a plurality of supporting silicon chip 103 on silicon supporting wafer 102.

Semiconductor epitaxy wafer 101 and supporting silicon wafer 102 are bonded to form a compound wafer. Then following the processes comprising removing the growth substrate, lithographing and etching, deposition, and dicing, to form a plurality of tunnel vertical semiconductor devices or chips (with or without static protection diodes).

FIG. 2 shows an embodiment of method of manufacturing tunnel vertical semiconductor devices or chips having static protection diodes. The manufacturing process in FIG. 2 is performed at wafer level. In order to simplifying drawing, employ only supporting silicon chip and semiconductor epitaxial chips in FIG. 2a to 2f.

FIG. 2a shows a semiconductor epitaxy chip and a supporting silicon chip with static protection diode 212. The structure of the semiconductor epitaxy chip comprises growth substrate 201, first-type cladding layer 202, active layer 203, second-type cladding layer 204, and reflector/Ohmic/bonding layer 205. Normally there is a buffer layer between growth substrate 201 and first-type cladding layer 202. Since the buffer layer will be removed with growth substrate 201, so there is no buffer layer shown in FIG. 2. The structure of a supporting silicon chip comprises first electrode 207 electrically connected to third electrode 211 by metal-plug 209, second electrode 206 electrically connected to fourth electrode 210 by metal-plug 208, isolation layer 213 electrically isolates first electrode 207 from second electrode 206. The two polarities of static protection diode 212 are electrically connected with first electrode 207 and second electrode 206 respectively.

The functions of reflector/Ohmic/bonding layer 205 are the following: (1) for LED, reflecting the light output emitted from the active layer; forming good Ohmic contact; easily bonding to a supporting chip; (2) for other semiconductor devices or chips, forming good Ohmic contact; easily bonding to a supporting chip.

FIG. 2b shows a semiconductor device or chip bonded to a supporting silicon chip.

Note: the bonding process is carried out at wafer level, i.e., a semiconductor epitaxial wafer is bonded to a supporting silicon wafer.

Removing growth substrate 201 and buffer layer (not shown in the FIG. 2) until first cladding layer 202 exposed. Then etching the epitaxial layer at pre-determined positions until first electrode 207 exposed (FIG. 2c). Depositing protection plug 214 on exposed first electrode 207. The isolation material of protection plug 214 is selected from a group comprising SiO2. Depositing current spreading layer 215 on the top surface of both first cladding layer 202 and protection plug 214(FIG. 2d). Etching both current spreading layer 215 and protection plug 214 at pre-determined positions until first electrode 207 exposed and forming a half-tunnel 216(FIG. 2e). Depositing metal into half-tunnel 216 to form half-tunnel-metal-plug 217. Half-tunnel-metal-plug 217 is electrically connected to first electrode 207. On current spreading layer 215, forming patterned electrode 218 which is electrically connected to the other end of half-tunnel-metal-plug 217(FIG. 2f).

The material of current spreading layer 215 is selected from a group of electrically conductive oxides and transparent metal thin films. Electrically conductive oxides comprise ITO, ZnO:Al, ZnGa2O4, SnO2:Sb, Ga2O3:Sn, In2O3:Zn, NiO, MnO, CuO, SnO, GaO. Transparent metal thin films comprise Ni/Au, Ni/Pt, Ni/Pd, Ni/Co, Pd/Au, Pt/Au, Ti/Au, Cr/Au, Sn/Au.

FIG. 2g to FIG. 2i show second embodiment of method of manufacturing tunnel vertical semiconductor devices or chips having static protection diodes. First, repeating the process steps in FIG. 2a to FIG. 2c. Then depositing protection plug 214 on first electrode 207(FIG. 2g). Etching protection plug 214 at pre-determined positions until first electrode 207 exposed to form half-tunnel 221 (FIG. 2h). In half-tunnel 221, depositing half-tunnel-metal-plug 222 which is electrically connected with first electrode 207. On the top surfaces of both protection plug 214 and first cladding layer 202, forming patterned electrode 223 to be electrically connected with half-tunnel-metal-plug 222 (FIG. 2i).

Note: a current spreading layer is not necessary if: (1) first cladding layer 202 is n-type cladding layer; (2) substantial second cladding layer is bonded to reflector/Ohmic/bonding layer; (3) selecting optimized patterned electrode. Therefore the issues of both the instability of ITO and light blocked by metal current spreading thin film may be avoid.

FIG. 2j shows third embodiment of method of manufacturing tunnel vertical semiconductor devices or chips having static protection diodes. First, repeat manufacturing process in FIG. 2a to FIG. 2c. Then repeat manufacturing process in FIG. 2g to FIG. 2i. Finally, depositing current spreading layer 224 on the top surfaces of both first cladding layer 202 and patterned electrode 223 (FIG. 2j).

FIG. 2f, FIG. 2i and FIG. 2j show respectively the first, second and third embodiment of tunnel vertical semiconductor devices or chips with static protection diodes of the present invention.

FIG. 3a, FIG. 3b and FIG. 3c show respectively the first, second and third embodiment of tunnel vertical semiconductor devices or chips without static protection diodes of the present invention. The process steps of manufacturing first, second and third embodiments of tunnel vertical semiconductor devices or chips of FIG. 3a, 3b and 3c are the same as that of first, second and third embodiments of tunnel vertical semiconductor devices or chips with static protection diodes of FIG. 2f, 2i and 2j respectively. The only difference is that there is no static protection diodes built in the supporting silicon chips for first, second and third embodiments of FIG. 3a, 3b and 3c.

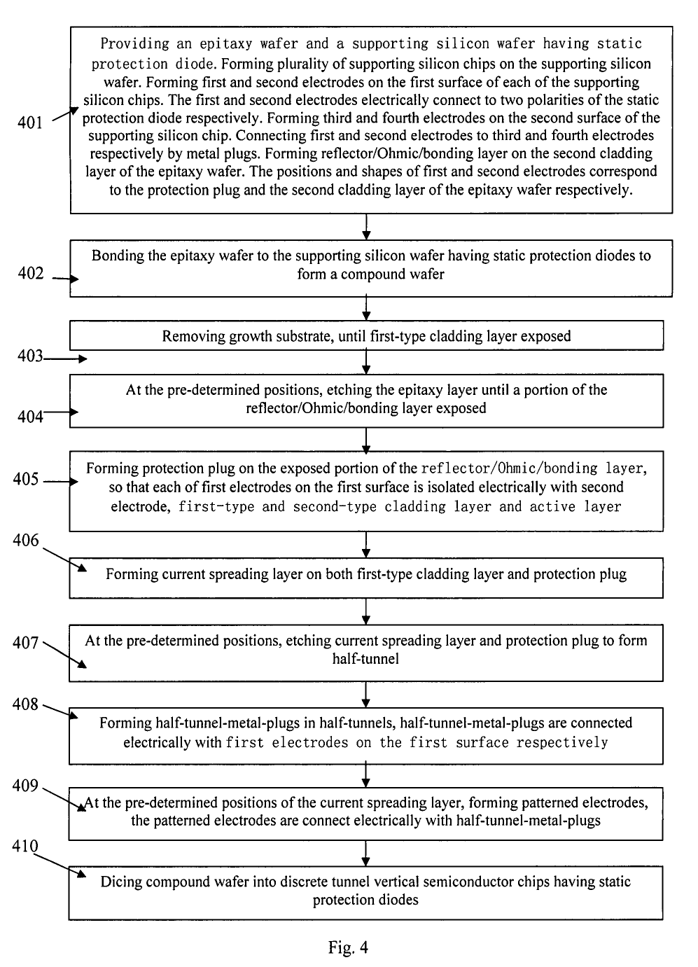

FIG. 4 shows schematically an embodiment of process steps of manufacturing tunnel vertical semiconductor devices or chips having static protection diodes.

Process 401: providing a semiconductor epitaxial wafer and a supporting silicon wafer having built-in static protection diodes. Forming plurality of supporting silicon chips. There are first and second electrodes on the first surface of each of the supporting silicon chips. There are third and fourth electrodes on the second surface of each of the supporting silicon chips. The first and second electrodes are respectively electrically connected to third and fourth electrodes via metal-plugs. Two electrodes on the same surface of the supporting silicon chip are electrically isolated. Depositing a patterned reflector/Ohmic/bonding layer on the second cladding layer of the semiconductor epitaxial wafer. A plurality of semiconductor epitaxial chips will be formed on pre-determined positions on the semiconductor epitaxial wafer. The position and shape of first and second electrodes of each of supporting silicon chips respectively correspond to that of protection plug formed later and portion of reflector/Ohmic/bonding layer.

Process 402: bonding the supporting silicon wafer to the semiconductor epitaxial wafer to form a compound wafer. The bonding methods comprise pressure-thermal method.

Process 403: removing the growth substrate of the semiconductor epitaxial wafer and the buffer layer until first cladding layer exposed. The methods of removing the growth substrate comprise laser lift-off, precision grinding/polishing, thermal separation, etching, and combination of above methods. The laser lift-off method is suitable for transparent growth substrates, such as sapphire, SiC, etc. The precision grinding/polishing method is suitable for all of growth substrates, such as silicon, GaAs, GaP, sapphire, SiC, etc. The etching method is suitable for easy-to-etching growth substrates, such as silicon, GaAs, GaP, etc.

Process 404: at pre-determined positions, etching semiconductor epitaxial layer (comprising first cladding layer, active layer, second cladding layer) until portion of the reflector/Ohmic/bonding layer, which is bonded to the first electrode on the first surface of the supporting silicon chip, exposed. The etching methods comprise dry and wet etching.

Process 405: Depositing a protection plug on the exposed portion of the reflector/Ohmic/bonding layer so that first electrode (and the portion of the reflector/Ohmic/bonding layer bonded to the first electrode) does not contact second electrode, first cladding layer, active layer and second cladding layer. The materials of the protection plug comprise SiO2. The top surface of the protection plug is substantially at the same level as that of first cladding layer.

Process 406: Depositing a current spreading layer on the top surfaces of both the first cladding layer and the protection plug. The materials of current spreading layer comprise transparent and electrically conductive oxides and transparent thin metal layers. The materials of the transparent and electrically conductive oxides comprise ITO, ZnO:Al, ZnGa2O4, SnO2:Sb, Ga2O3:Sn, In2O3:Zn, NiO, MnO, CuO, SnO and GaO. The materials of the transparent thin metal layer comprise Ni/Au, Ni/Pt, Ni/Pd, Ni/Co, Pd/Au, Pt/Au, Ti/Au, Cr/Au and Sn/Au.

Process 407: at pre-determined positions, etching the current spreading layer and the protection plugs until the portions of the reflector/Ohmic/bonding layers, which is bonded to the first electrodes, exposed and forming half-tunnels. The methods of etching comprise dry and wet etching.

Process 408: Forming half-tunnel-metal-plugs in each of half-tunnels. Half-tunnel-metal-plugs are electrically connected to the exposed portion of the reflector/Ohmic/bonding layer.

Process step 409: at pre-determine positions on the surfaces of the current spreading layer and half-tunnel-metal-plugs, depositing optimized patterned electrodes which being electrically connected with the half-tunnel-metal-plugs so that the current distribution is more uniform.

Process 410: dicing the compound wafer into single tunnel vertical semiconductor devices or chips.

Note: the process of FIG. 4 manufactures tunnel vertical semiconductor devices or chips with or without static protection diodes depending on whether the supporting silicon wafers with or without static protection diodes.

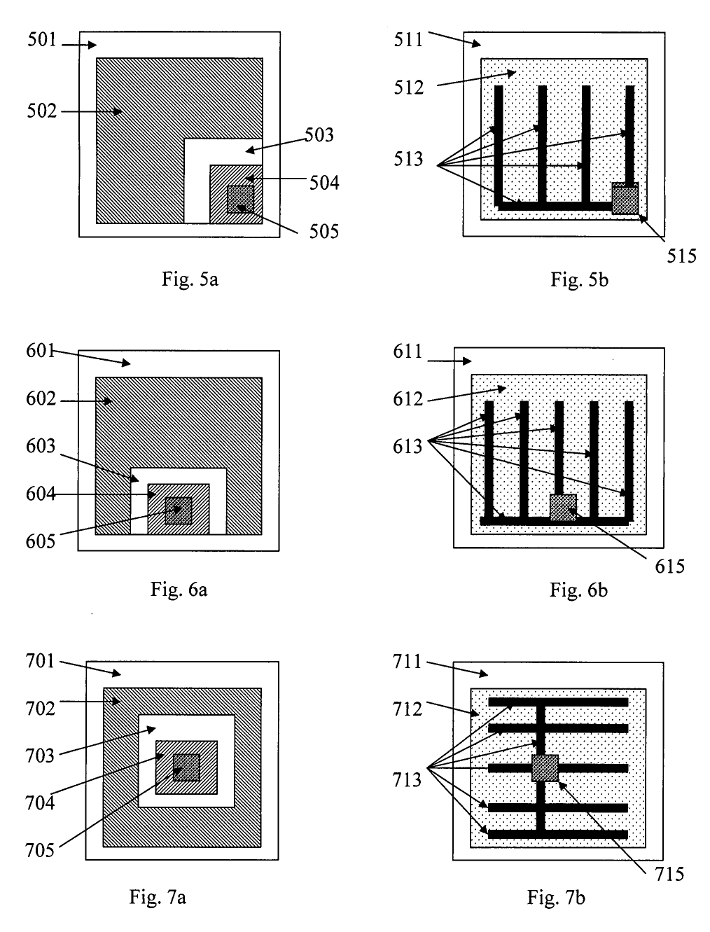

FIG. 5a shows an embodiment of the positions and shapes of first electrode, second electrode and isolation layer on first surface of a supporting silicon chip. First electrode 504 is isolated from second electrode 502 by isolation layer 503. The shape of first electrode 504 can be in other shapes, such as circle. Dark region 505 shows the position and shape of a half-tunnel-metal-plug which will be electrically connected to first electrode 504 later on. Half-tunnel-metal-plug 515 can be in other shape, such as circle. First electrode 504 and dark region 505 is at a corner of the silicon chip.

FIG. 5b shows an embodiment of positions and shapes of a patterned electrode of a tunnel vertical semiconductor chip which corresponding to that of the supporting silicon chip of FIG. 5a. The tunnel vertical semiconductor chip 511 comprises current spreading layer 512 and patterned electrode 513 on the top surface. Patterned electrode 513 has a shape of fork. Patterned electrode 513 is electrically connected to first electrode 504 in FIG. 5a via half-tunnel-metal-plug 515.

Note: the current spreading layer is not necessary.

FIG. 6a shows second embodiment of positions and shapes of first electrode, second electrode and isolation layer of a supporting silicon chip. First electrode 604 is isolate from second electrode 602 by isolation layer 603. First electrode 604 can be in other shape, for example, circle. Dark region 605 shows the position and shape of a half-tunnel-metal-plug which will electrically connect to first electrode 604. Half-tunnel-metal-plug 615 can be in other shape, such as circle. First electrode 604 and dark region 605 is along a side of the silicon chip.

FIG. 6b shows an embodiment of positions and shapes of patterned electrode of a tunnel vertical semiconductor chip which corresponding to that of the supporting silicon chip of FIG. 6a. The tunnel vertical semiconductor chip 611 has current spreading layer 612 and patterned electrode 613 on the top surface. Patterned electrode 613 has a shape of fork. Patterned electrode 613 is electrically connected to first electrode 604 in FIG. 6a via half-tunnel-metal-plug 615.

Note: current spreading layer is not necessary.

FIG. 7a shows third embodiment of positions and shapes of first electrode, second electrode and isolation layer of a supporting silicon chip. First electrode 704 is isolate from second electrode 702 by isolation layer 703. First electrode 704 can be in other shape, for example, circle. Dark region 705 shows the position and shape of a half-tunnel-metal-plug which will be electrically connected to first electrode 704. Half-tunnel-metal-plug 715 can be in other shape, such as circle. First electrode 704 and dark region 705 are at the center portion of the supporting silicon chip.

FIG. 7b shows an embodiment of positions and shapes of patterned electrode of a tunnel vertical semiconductor chip which corresponding to that of the supporting silicon chip of FIG. 7a. The tunnel vertical semiconductor chip 711 has current spreading layer 712 and patterned electrode 713 on the top surface. Patterned electrode 713 has a shape of fork. Patterned electrode 713 is electrically connected to first electrode 704 in FIG. 7a via half-tunnel-metal-plug 715.

Note: current spreading layer 712 is not necessary.

Patterned electrodes may have other shapes, for example, connected grid, connected rings, to distribute electric current more uniformly and block less output light.

Although the description above contains many specifications, these should not be construed as limiting the scope of the present invention but as merely providing illustrations of some of the presently preferred embodiments of the present invention. Therefore the scope of the present invention should be determined by the claims and their legal equivalents, rather than by the examples given.

We claim:

1. A tunnel vertical semiconductor device or chip comprising:
a supporting chip; wherein said supporting chip comprising first and second surfaces on the opposite sides; wherein said second surface of said supporting chip comprising third and fourth electrodes; wherein said third and fourth electrodes electrically isolated to each other; wherein each of said third and fourth electrodes electrically connected to at least one metal-plug passing through said supporting chip;
a semiconductor epitaxial layer; wherein said semiconductor epitaxial layer being bonded to said first surface of said supporting chip; one surface of said semiconductor epitaxial layer exposed; wherein said semiconductor epitaxial layer being electrically connected to said fourth electrode on said second surface of said supporting chip via at least one of said metal-plugs.
at least one protection plug; wherein said protection plug passing through said semiconductor epitaxial layer; wherein said protection plug comprising a half-tunnel passing through said protection plug; wherein one surface of said protection plug exposed;
at least one half-tunnel-metal-plug; wherein said half-tunnel-metal-plug deposited in said half-tunnel and passing through said protection plugs; wherein said half-tunnel-metal-plug electrically connected to one of said metal-plug; wherein one surface of said half-tunnel-metal-plug exposed;
at least one patterned electrode; wherein said patterned electrode deposited on said exposed surfaces of said semiconductor epitaxial layer, said protection plug and said half-tunnel-metal-plug; wherein said patterned electrode being electrically connected to said third electrode on said second surface of said supporting chip via both at least one of said half-tunnel-metal-plugs and at least one of said metal-plugs.

2. The tunnel vertical semiconductor chip of claim 1, wherein the material of said supporting chip is selected from a group comprising supporting silicon chips with built-in static protection diodes and supporting chips without built-in static protection diodes.

3. The tunnel vertical semiconductor chip of claim 1, wherein the material of said semiconductor epitaxial layer is selected from a group comprising: (1) GaN based materials comprising combinations of elements of gallium, aluminum, indium and nitrogen, such as, GaN, AlGaN, GaInN, AlGaInN; wherein said GaN based epitaxial layer comprising polar and non-polar epitaxial layers; (2) GaP based materials comprising combination of elements of gallium, aluminum, indium and phosphor, such as, GaP, AlGaP, GaInP, AlGaInP; (3) GaPN based materials comprising combinations of elements of gallium, aluminum, indium, nitrogen and phosphor, such as, GaNP, AlGaNP, GaInNP, AlGaInNP; (4) ZnO based materials comprising ZnO.

4. The tunnel vertical semiconductor chip of claim 1, wherein said semiconductor epitaxial layer comprising first cladding layer, active layer and second cladding layer; the structures of said active layer comprising bulk, single quantum well, multiple quantum well, quantum dot and quantum line.

5. The tunnel vertical semiconductor chip of claim 4, wherein the material of said semiconductor epitaxial layer is selected from a group comprising (1) GaN based materials comprising combination of elements of gallium, aluminum, indium and nitrogen, such as, GaN, AlGaN, GaInN, AlGaInN; wherein said GaN based epitaxial layer comprising polar and non-polar epitaxial layers; (2) GaP based materials comprising combination of elements of gallium, aluminum, indium and phosphor, such as, GaP, AlGaP, GaInP, AlGaInP; (3) GaPN based materials comprising combination of elements of gallium, aluminum, indium, nitrogen and phosphor, such as, GaNP, AlGaNP, GaInNP, AlGaInNP; (4) ZnO based materials comprising ZnO.

6. The tunnel vertical semiconductor chip of claim 1, wherein the material of said protection plug is selected from a group comprising electrical isolation materials, such as SiO2.

7. The tunnel vertical semiconductor chip of claim 1, wherein the pattern of said patterned electrodes is selected from a group comprising forks, connected rings and connected grids.

8. The tunnel vertical semiconductor chip of claim 1, further comprising a reflector/Ohmic/bonding layer deposited between said semiconductor epitaxial layer and said first surface of said supporting chip; wherein said semiconductor epitaxial layer being electrically connected to said fourth electrode on said second surface of said supporting chip.

9. The tunnel vertical semiconductor chip of claim 1, further comprising first electrode and second electrode; wherein said first and second electrodes deposited between said semiconductor epitaxial layer and said first surface of said supporting chip; wherein said first and second electrodes isolated to each other; wherein said first and second electrodes being respectively electrically connected to third and fourth electrodes via metal-plugs; wherein said patterned electrodes being electrically connected to said third electrode on said second surface of said supporting chip via at least one of said half-tunnel-metal-plugs, at least one of said metal-plugs and said first electrode; said semiconductor epitaxial layer being electrically connected to said fourth electrode on said second surface of said supporting chip.

10. The tunnel vertical semiconductor chip of claim 9, further comprising a reflector/Ohmic/bonding layer; wherein said reflector/Ohmic/bonding layer deposited between said semiconductor epitaxial layer and said second electrode; wherein said semiconductor epitaxial layer being electrically connected to said fourth electrode on said second surface of said supporting chip.

11. The tunnel vertical semiconductor chip of claim 9, further comprising a reflector/Ohmic/bonding layer; wherein said reflector/Ohmic/bonding layer deposited between said half-tunnel-metal-plugs and said first electrode; wherein said patterned electrodes being electrically connected to said third electrode on said second surface of said supporting chip.

12. The tunnel vertical semiconductor chip of claim 1, further comprising a current spreading layer; wherein said current spreading layer deposited on the top surface of said semiconductor epitaxial layer and between said semiconductor epitaxial layer and said patterned electrode.

13. The tunnel vertical semiconductor chip of claim 1, further comprising a current spreading layer; wherein said current spreading layer deposited on the top surfaces of both said semiconductor epitaxial layer and said patterned electrode.

14. A manufacturing method producing the tunnel vertical semiconductor devices or chips of claim 1.

15. A manufacturing method producing the tunnel vertical semiconductor devices or chips of claim 14, comprising the following process steps:
(1) providing a semiconductor epitaxial wafer and a supporting wafer; forming a plurality of supporting chips on said supporting wafer by forming first and second electrodes on the first surface of each of said supporting chips; forming third and fourth electrodes on the second surface of each of said supporting chips; said first and second electrodes being respectively electrically connected to third and fourth electrodes via metal-plugs; wherein two said electrodes on the same surface of each of said supporting chips being electrically isolated; wherein said supporting wafer being selected from a group comprising a supporting wafer without static protection diode and a supporting silicon wafer with static protection diodes; depositing patterned reflector/Ohmic/bonding layer on the second cladding layer of said semiconductor epitaxial wafer; a plurality of semiconductor epitaxial chips being formed on pre-determined positions on the semiconductor epitaxial wafer later;
(2) bonding said supporting wafer to said semiconductor epitaxial wafer to form a compound wafer;
(3) removing the growth substrate of said semiconductor epitaxial wafer and the buffer layer until first cladding layer exposed;
(4) etching semiconductor epitaxial layer at pre-determined positions until a portion of said patterned reflector/Ohmic/bonding layer, which being bonded to said first electrode on said first surface of said supporting wafer, exposed;
(5) depositing a protection plug on said exposed portion of reflector/Ohmic/bonding layer so that said first electrode (and said portion of said reflector/Ohmic/bonding layer bonded to said first electrode) being isolated from said second electrode and said semiconductor epitaxial layer;
(6) etching said protection plugs at pre-determined positions until said portion of said reflector/Ohmic/bonding layer bonded to said first electrodes exposed to form half-tunnels;
(7) forming half-tunnel-metal-plugs in half tunnels which being electrically connected to said exposed portion of said reflector/Ohmic/bonding layer;
(8) at pre-determine positions on said exposed surfaces of said first cladding layer, said protection plugs and said half-tunnel-metal-plugs, depositing patterned electrodes which being electrically connected to said half-tunnel-metal-plugs so that the current distribution being more uniform;
(9) dicing said compound wafer into single tunnel vertical semiconductor devices or chips.
